(19) United States
(12) Patent Application Publication
(10) Pub. No.: US 2021/0017645 A1
(43) Pub. Date: Jan. 21, 2021

(54) RESOLVING SPONTANEOUS ARCING DURING THICK FILM DEPOSITION OF HIGH TEMPERATURE AMORPHOUS CARBON DEPOSITION

(71) Applicant: Applied Materials, Inc., Santa Clara, CA (US)

(72) Inventors: Lu XU, Santa Clara, CA (US); Byung Seok KWON, San Jose, CA (US); Viren KALSEKAR, Sunnyvale, CA (US); Vinay K. PRABHAKAR, Cupertino, CA (US); Prashant Kumar KULSHRESHTHA, San Jose, CA (US); Dong Hyung LEE, Danville, CA (US); Kwangduk Douglas LEE, Redwood City, CA (US)

(21) Appl. No.: 17/040,788

(22) PCT Filed: Apr. 9, 2019
(86) PCT No.: PCT/US2019/026576

§ 371 Date: Sep. 23, 2020

Related U.S. Application Data
(60) Provisional application No. 62/795,242, filed on Jan. 22, 2019.
(60) Provisional application No. 62/655,599, filed on Apr. 10, 2018.

(51) Int. Cl. C23C 16/458; C23C 16/34; C23C 16/509; C23C 16/40; C23C 16/04; C23C 16/455; C23C 16/26

(52) U.S. Cl. CPC C23C 16/4585; C23C 16/34; C23C 16/5096; C23C 16/26; C23C 16/042; C23C 16/45544; C23C 16/40

(57) ABSTRACT

Embodiments of the present invention generally relate to an apparatus for reducing arcing during thick film deposition in a plasma process chamber. In one embodiment, an edge ring including an inner edge diameter that is about 0.28 inches to about 0.38 inches larger than an outer diameter of a substrate is utilized when depositing a thick (greater than two microns) layer on the substrate. The layer may be a dielectric layer, such as a carbon hard mask layer, for example an amorphous carbon layer. With the 0.14 inches to 0.19 inches gap between the outer edge of substrate and the inner edge of the edge ring during the deposition of the thick layer, substrate support surface arcing is reduced while the layer thickness uniformity is maintained.

### BACKGROUND

### Field

Embodiments of the present disclosure generally relate to an apparatus for reducing arcing during thick film deposition in a plasma process chamber.

### Description of the Related Art

Plasma-enhanced chemical vapor deposition (PECVD) process is a chemical process where electro-magnetic energy is applied to at least one precursor gas or precursor vapor to transform the precursor into a reactive plasma. There are many advantages in using PECVD, including but not limited to lowering the temperature required to form a film, increasing the rate of formation of the film, and enhancing the properties of the layers being formed.

PECVD processes have been increasingly prevalent in the formation of hard masks. As devices evolve from a stack including 64 oxide/nitride alternating layers to 96 or 128 oxide/nitride alternating layers, the thickness of the hard mask, typically a carbon containing hard mask, increases to greater than three microns. When the thickness of the carbon hard mask is greater than two microns, the risk of local charge buildup and inconsistent charge dissipation path increases, due to prolonged deposition time or increased plasma power. The local charge buildup and inconsistent charge dissipation path can lead to failure due to instant discharge, in the form of arcing. Statistically, in thicker regimes of the hard mask, the defect rate caused by arcing exponentially increases (from about 0.3 percent to about 30 percent). Due to increased arcing rate, future devices with 96 or 128 oxide/nitride alternating layers would not be feasible, limiting extendibility towards future devices and applications.

Therefore, an improved apparatus is needed to reduce arcing during thick film deposition in a plasma process chamber.

### SUMMARY

Embodiments of the present disclosure generally relate to an apparatus for reducing arcing during thick film deposition in a plasma process chamber. In one embodiment, a ring includes a body having a top surface, a bottom surface parallel to the top surface, an inclined surface connecting the top surface to the bottom surface, the inclined surface and the bottom surface forming an angle ranging from about 20 degrees to about 80 degrees, an outer edge connecting the top surface to the bottom surface, and an inner edge defined by a junction of the inclined surface and the bottom surface, the inner edge having a diameter ranging from about 12.08 inches to about 12.18 inches.

In another embodiment, a process chamber for forming a layer on a substrate includes a chamber body, a lid disposed over the chamber body, a substrate support disposed in the chamber body, and an edge ring disposed on the substrate support. The edge ring includes a body having an outer edge and an inner edge, and a diameter of the inner edge being about 0.28 inches to about 0.38 inches larger than a diameter of the substrate.

In another embodiment, a method includes placing a substrate into a process chamber, the substrate being surrounded by an edge ring, a distance between the substrate and an inner edge of the edge ring ranging from about 0.14 inches to about 0.19 inches, and forming a dielectric layer on the substrate, and the dielectric layer has a thickness greater than about two microns

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 is a schematic cross-sectional view of a plasma process chamber according to one embodiment described herein.

FIG. 2 is a cross-sectional perspective view of an edge ring of FIG. 1 according to one embodiment described herein.

FIG. 3 is a flow chart illustrating a method for forming a layer in the plasma process chamber of FIG. 1 according to one embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to an apparatus for reducing arcing during thick film deposition in a plasma process chamber. In one embodiment, an edge ring including an inner diameter that is about 0.28 inches to about 0.38 inches larger than an outer diameter of a substrate is utilized when depositing a thick (greater than two microns) layer on the substrate. The layer may be a dielectric layer, such as a carbon hard mask layer, for example an amorphous carbon layer. With the 0.14 inches to 0.19 inches gap between the outer edge of substrate and the inner edge of the edge ring during the deposition of the thick layer, substrate support surface arcing is reduced while the layer thickness uniformity is maintained.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

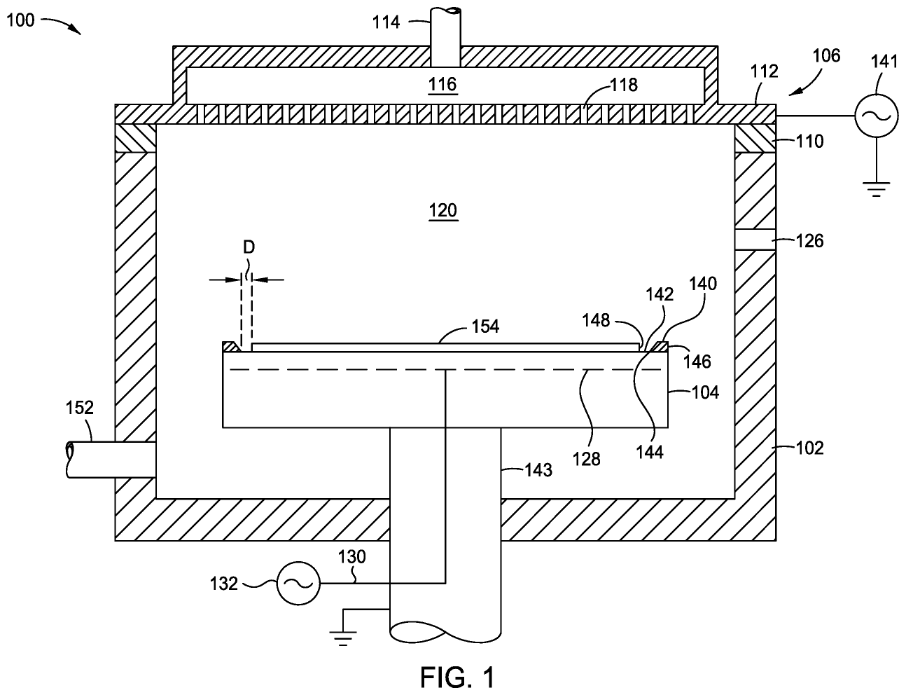

FIG. 1 is a schematic cross-sectional view of a plasma process chamber 100 according to one embodiment described herein. The process chamber 100 may be a PECVD chamber or other plasma enhanced process chamber. An exemplary process chamber which may benefit from the embodiments described herein is the PRODUCER® series of PECVD enabled chambers, available from Applied Materials, Inc., Santa Clara, Calif. It is contemplated that other similarly equipped process chambers from other manufacturers may also benefit from the embodiments described herein. The process chamber 100 includes a chamber body 102, a substrate support 104 disposed inside the chamber body 102, and a lid assembly 106 coupled to the chamber body 102 and enclosing the substrate support 104 in a processing region 120. The lid assembly 106 includes a gas distributor 112. Substrates 154 are provided to the processing region 120 through an opening 126 formed in the chamber body 102.

An isolator 110, which may be a dielectric material such as a ceramic or metal oxide, for example aluminum oxide and/or aluminum nitride, separates the gas distributor 112 from the chamber body 102. The gas distributor 112 features openings 118 for admitting process gases into the processing region 120. The process gases may be supplied to the process chamber 100 via a conduit 114, and the process gases may enter a gas mixing region 116 prior to flowing through the openings 118. An exhaust 152 is formed in the chamber body 102 at a location below the substrate support 104. The exhaust 152 may be connected to a vacuum pump (not shown) to remove unreacted species and by-products from the processing chamber 100.

The gas distributor 112 may be coupled to an electric power source 141, such as an RF generator or a DC power source. The DC power source may supply continuous and/or pulsed DC power to the gas distributor 112. The RF generator may supply continuous and/or pulsed RF power to the gas distributor 112. The electric power source 141 is turned on during the operation to supply an electric power to the gas distributor 112 to facilitate formation of a plasma in the processing region 120.

The substrate support 104 may be formed from a ceramic material, for example a metal oxide or nitride or oxide/nitride mixture such as aluminum, aluminum oxide, aluminum nitride, or an aluminum oxide/nitride mixture. The substrate support 104 is supported by a shaft 143. The substrate support 104 may be grounded. An electrode 128 is embedded in the substrate support 104. The electrode 128 may be a plate, a perforated plate, a mesh, a wire screen, or any other distributed arrangement. The electrode 128 is coupled to an electric power source 132 via a connection 130. The electric power source 132 may be an RF generator, and the electric power source 132 may be utilized to control properties of the plasma formed in the processing region 120, or to facilitate generation of the plasma within the processing region 120. For example, the electric power source 141 and the electric power source 132 may be tuned to two different frequencies to promote ionization of multiple species in the processing region 120. In one example, the electric power source 141 and the electric power source 132 may be utilized to generate a capacitively-couple plasma within the processing region 120.

The substrate support 104 includes a surface 142 for supporting the substrate 154 and an edge ring 140. The substrate 154 and the edge ring 140 may be concentrically disposed on the surface 142 of the substrate support 104. The edge ring may be fabricated from the same material as the substrate support. The edge ring 140 includes an inner edge 144 and an outer edge 146. The substrate 154 includes an outer edge 148. In one embodiment, a distance D between the outer edge 148 of the substrate 154 and the inner edge 144 of the edge ring 140 ranges from about 0.14 inches to about 0.19 inches. With the distance D ranging from about 0.14 inches to about 0.19 inches during the deposition of a thick layer, such as a hard mask having a thickness of greater than 2 microns, arcing on the surface 142 of the substrate support 104 is reduced while the layer thickness uniformity of the thick layer is maintained.

Conventionally, the distance between the outer edge 148 of the substrate 154 and an inner edge of a conventional edge ring is about 0.2 to 0.8 inches. As charge accumulates beyond the dielectric threshold during the deposition of a thick layer, instant discharge occurs at the surface 142 of the substrate support 104 between the substrate 154 and the conventional edge ring.

It has been discovered that by reducing the distance between the outer edge 148 of the substrate 154 and the inner edge 144 of the edge ring 140 to about 0.14 inches to about 0.19 inches, arcing at the surface 142 of the substrate support 104 between the substrate 154 and the edge ring 140 is minimized. In one embodiment, the substrate 154 has a diameter of about 11.8 inches and the diameter of the inner edge 144 of the edge ring 140 is about 12.2 inches. Table 1 demonstrates the benefits of having the edge ring 140.

TABLE 1

| | Number of | |
|---|---|---|
| Condition | substrates tested | Arcing observed |
| Depositing amorphous carbon | 55 | Yes |
| layer having a thickness of five | | |
| microns on a substrate having | | |
| a diameter of 11.8 inches | | |
| using an edge ring having an | | |
| inner edge diameter of 12.6 | | |
| inches (distance between the | | |
| substrate and the edge ring is | | |
| 0.4 inches) with 600 V applied | | |
| to the electrode embedded in | | |
| the substrate support | | |
| Depositing amorphous carbon | 55 | No |
| layer having a thickness of five | | |
| microns on a substrate having | | |
| a diameter of 11.8 inches | | |
| using an edge ring having an | | |
| inner edge diameter ranging | | |
| from 12.08 to 12.18 inches | | |
| (distance between the | | |
| substrate and the edge ring | | |
| ranging from 0.14 to 0.19 | | |
| inches) with 600 V applied to | | |
| the electrode embedded in the | | |
| substrate support | | |

In the examples of table 1, 600 V was applied to the electrode 128 to intentionally increase charge buildup during the deposition. Typically the voltage applied to the electrode 128 during normal thick layer deposition is less than 600 V. Even with the high voltage, such as 600 V, applied to the electrode 128, arcing was not observed with the edge ring 140.

It has also been discovered that if the distance D is less than 0.1 inches, such as 0 inches (edge ring in contact with the substrate), the thickness uniformity of the thick layer deposited on the substrate 154 is reduced. Thus, with the distance D ranging from about 0.14 inches to about 0.19 inches during the deposition of a thick layer, such as a hard mask having a thickness of greater than 2 microns, arcing on the surface 142 of the substrate support 104 is reduced while the layer thickness uniformity is maintained. In one embodiment, the substrate 154 has a diameter of about 11.8 inches, and the diameter of the inner edge 144 of the edge ring 140 ranges from about 12.08 inches to about 12.18 inches. In one embodiment, the diameter of the inner edge 144 of the edge ring 140 is about 102.4 percent to about 103.2 percent of the diameter of the substrate 154. In one embodiment, the opening defined by the inner edge 144 of the edge ring 140 is about 104.8 percent to about 106.5 percent of the area of a major surface of the substrate 154.

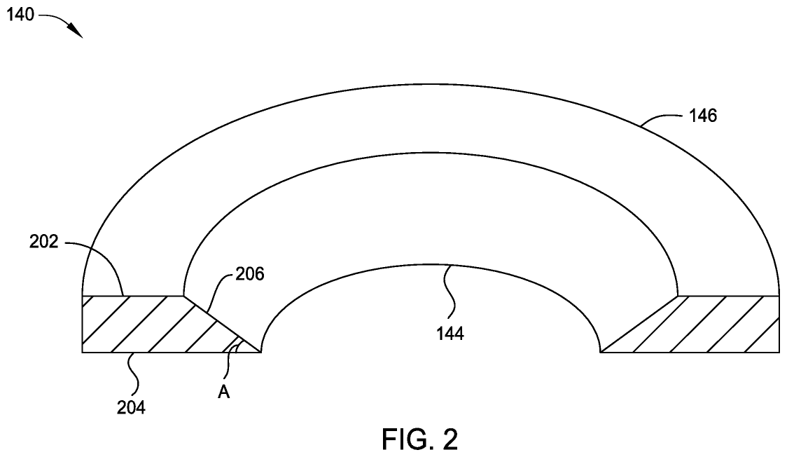

FIG. 2 is a cross-sectional perspective view of the edge ring 140 of FIG. 1 according to one embodiment described herein. As shown in FIG. 2, the edge ring 140 includes the inner edge 144 and the outer edge 146. The edge ring 140 further includes a top surface 202 and a bottom surface 204, which may be parallel to one another. The top surface 202 is connected to the bottom surface 204 by an inclined surface 206, and the inner edge 144 is the junction of the bottom surface 204 and the inclined surface 206. An angle A is formed by the bottom surface 204 and the inclined surface 206, and the angle A ranges from about 20 degrees to about 80 degrees, such as from about 40 degrees to about 70 degrees, for example from about 55 degrees to about 65 degrees. If the angle A is smaller than 20 degrees, such as 10 degrees, the inner edge 144 may chip easily, and arcing can occur at the chipped location.

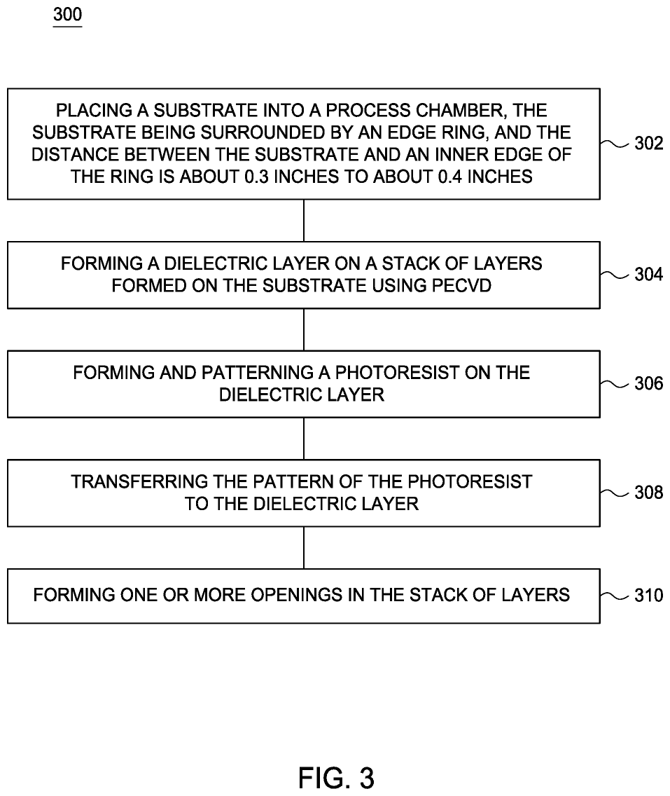

FIG. 3 is a flow chart illustrating a method 300 for forming a layer in the plasma process chamber 100 of FIG. 1 according to one embodiment described herein. The method 300 starts at block 302, at which a substrate, such as the substrate 154 shown in FIG. 1, is placed into a process chamber, such as the process chamber 100 shown in FIG. 1. The substrate is surrounded by an edge ring, such as the edge ring 140 shown in FIG. 1, and the distance between the substrate and an inner edge of the edge ring ranges from about 0.14 inches to about 0.19 inches. The substrate includes a stack of layers, such as 96 or 128 alternating oxide/nitride layers, for example silicon oxide and silicon nitride layers.

Next, at block 304, a dielectric layer, such as an amorphous carbon layer, is deposited on the stack of layers using PECVD. The dielectric layer has a thickness of greater than two microns, such as about three microns. During the deposition of the dielectric layer, there is no arcing between the substrate and the inner edge of the edge ring. At block 306, a photoresist is subsequently formed and patterned on the dielectric layer, and the pattern is transferred to the dielectric layer, as shown at block 308. Next, at block 310, one or more openings are formed in the stack of layers. The one or more openings may be formed by one or more etching processes.

By utilizing an edge ring having an inner edge diameter that is about 0.28 inches to about 0.38 inches larger than an outer diameter of a substrate during the deposition of a layer having a thickness greater than about two microns on the substrate, substrate support surface arcing is reduced while the layer thickness uniformity is maintained.

While the foregoing is directed to embodiments of the present disclosure, other and further embodiments of the disclosure may be devised without departing from the basic scope thereof.

1. A ring, comprising:
a body, comprising:
a top surface;
a bottom surface parallel to the top surface;
an inclined surface connecting the top surface to the bottom surface, the inclined surface and the bottom surface forming an angle ranging from about 20 degrees to about 80 degrees;
an outer edge connecting the top surface to the bottom surface; and
an inner edge defined by a junction of the inclined surface and the bottom surface, the inner edge having a diameter ranging from about 12.08 inches to about 12.18 inches.

2. The ring of claim 1, wherein the ring is fabricated from a ceramic material.

3. The ring of claim 1, wherein the angle ranges from about 40 degrees to about 70 degrees.

4. The ring of claim 1, wherein the angle ranges from about 55 degrees to about 65 degrees.

5. A process chamber for forming a layer on a substrate, comprising:
a chamber body;
a lid disposed over the chamber body;
a substrate support disposed in the chamber body; and
an edge ring disposed on the substrate support, the edge ring comprising:
a body, comprising:
an outer edge; and
an inner edge, a diameter of the inner edge being about 0.28 inches to about 0.38 inches larger than a diameter of the substrate.

6. The process chamber of claim 5, wherein the diameter of the inner edge ranges from about 12.08 inches to about 12.18 inches.

7. The process chamber of claim 5, wherein the diameter of the inner edge is about 102.4 percent to about 103.2 percent of a diameter of the substrate.

8. The process chamber of claim 5, wherein the edge ring is fabricated from a ceramic material.

9. The process chamber of claim 5, wherein the edge ring further comprises:
a top surface;
a bottom surface parallel to the top surface; and
an inclined surface connecting the top surface to the bottom surface.

10. The process chamber of claim 9, wherein the inner edge is defined by a junction of the inclined surface and the bottom surface.

11. A method, comprising:
placing a substrate into a process chamber, the substrate being surrounded by an edge ring, a distance between the substrate and an inner edge of the edge ring ranging from about 0.14 inches to about 0.19 inches; and
forming a dielectric layer on the substrate, the dielectric layer having a thickness greater than about two microns.

12. The method of claim 11, wherein the substrate includes a stack of layers, and the dielectric layer is formed on the stack of layers.

13. The method of claim 12, wherein the stack of layers comprises a plurality of alternating oxide and nitride layers.

14. The method of claim 13, further comprising forming and patterning a photoresist on the dielectric layer.

15. The method of claim 14, further comprising forming one or more openings in the stack of layers.

16. The process chamber of claim 5, further comprising an electrode embedded in the substrate support.

17. The process chamber of claim 9, wherein the inclined surface and the bottom surface form an angle ranging from about 20 degrees to about 80 degrees.

18. The process chamber of claim 17, wherein the angle ranges from about 40 degrees to about 70 degrees.

19. The process chamber of claim 18, wherein the angle ranges from about 55 degrees to about 65 degrees.

20. The method of claim 11, wherein the dielectric layer is an amorphous carbon layer.
